(19) United States
(12) Patent Application Publication
(10) Pub. No.: US 2005/0072975 A1
(43) Pub. Date: Apr. 7, 2005

(54) PARTIALLY DEPLETED SOI MOSFET DEVICE

(76) Inventors: Shiao-Shien Chen, Hsin-Chu City (TW); Lu-Shiang Huang, Hsin-Chu City (TW); Tien-Hao Tang, Taipei Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/605,481

(22) Filed: Oct. 2, 2003

(51) Int. Cl. H01L 29/76

(52) U.S. Cl. 257/66

(57) ABSTRACT

A partially depleted SOI MOS device includes a well of first conductivity type isolated in a thin film body of an SOI substrate. The SOI substrate encompasses the thin film body, a support substrate, and a buried oxide layer interposed between the thin film body and the support substrate. A gate dielectric layer is disposed on a surface of the well. A polysilicon gate is patterned on the gate dielectric layer. The polysilicon gate consists of a first gate section of first conductivity type overlapping with an extended well region of the well and a second gate section of second conductivity type lying across the well, whereby a tunneling connection is formed between the first gate section and the extended well region of said well. Source and drain regions of second conductivity type are formed on opposite sides of the second gate section.

### BACKGROUND OF INVENTION

1. Field of the Invention

The present invention relates in general to semiconductor devices, and in particularly, to high performance partially depleted (PD) SOI MOSFET devices. According to one preferred embodiment of the present invention, a PD SOI MOSFET device with high current-driving capability is provided.

2. Description of the Prior Art

Silicon-on-insulator (SOI) technology has long been used in many special applications such as radiation-hardened or high-voltage integrated circuits. It is only in recent years that SOI has emerged as a serious contender for low-power high-performance applications. The primary reason is the power consumption of scaled bulk complementary metal-oxide-semiconductor (CMOS) technology. With the bulk CMOS 0.15 um technology, the effective channel length does not work satisfactorily within the power constraints of the intended low-voltage applications. Having the feature that the circuit elements are isolated dielectrically, SOI technology significantly reduces junction capacitances and allows the circuits to operate at high speed or substantially lower power at the same speed. The device structure also eliminates latch up in bulk CMOS, improves the short channel effect and soft error immunity.

However, despite these advantages of the SOI technology, this technology faces some key challenges in process and manufacturing availability, devices and circuit design issues. At the process level, neither bonded nor separation by implanted oxygen (SIMOX) SOI are mature enough for mass production of low-cost, low-defect-density substrates. At device and circuit level, the floating body effect and the so-called kink effect in partially depleted devices poses major challenges for large-scale design.

Various schemes are known for alleviating the floating body effect. For example, U.S. Statutory Invention Registration (SIR) Reg. No. H1435 filed Oct. 21, 1991, by Cherne et al., entitled “SOI CMOS device having body extension for providing sidewall channel stop and bodytie”, which is incorporated herein by reference, discloses an SOI thin film MOS mesa architecture having its body/channel region extended beyond the source and drain regions and the impurity concentration is increased at a selected portion of the extended body region, so as to provide both a body tie access location which enables the body/channel region to be terminated to a prescribed bias voltage (e.g. Vss), and a channel stop region that is effective to functionally interrupt a current leakage path or parasitic N-channel that may be induced along sidewall surface of the P-type material of the body/channel region.

U.S. Pat. No. 5,343,051 filed May 10, 1993, by Yamaguchi et al., entitled “Thin-film SOI MOSFET”, assigned to Mitsubishi Denki Kabushiki Kaisha (Tokyo, JP), which is incorporated herein by reference, describes an MOS field effect transistor comprising a channel region of a first conductivity type formed in a semiconductor layer on an insulator substrate, source and drains regions of a second conductivity type formed in contact with one and the other sides of the channel region respectively in the semiconductor layer, a body region of the first conductivity type having a higher impurity concentration than that of the channel region, and being formed in contact with at least a part of the channel region and at least a part of a periphery of the source region in the semiconductor layer, a gate dielectric thin film and a gate electrode formed on the channel region, a first conductor connected to the source region and the body region in common, a second conductor connected to the gate electrode, and a third conductor connected to the drain region.

U.S. Pat. No. 5,920,093 filed Apr. 7, 1997, by Huang et al., entitled “SOI FET having gate sub-regions conforming to t-shape”, assigned to Motorola, Inc. (Schaumburg, Ill.), which is incorporated herein by reference, discloses a semiconductor device formed in a silicon-on-insulator (SOI) substrate. The semiconductor device has a channel region that is controlled by a gate structure. The channel region has a doping profile that is essentially uniform where the channel region is under the gate structure. This eliminates the parasitic channel region that is common with conventional field effect transistors (FETs) that are formed in SOI substrates. Consequently, the semiconductor device of the present invention does not suffer from the “kink” problem that is common to conventional FET devices.

U.S. Pat. No. 5,811,855 filed Dec. 29, 1997, by Tyson et al., entitled “SOI combination body tie”, assigned to United Technologies Corporation (Hartford, CT), which is incorporated herein by reference, discloses an H-transistor, fabricated in an SOI substrate, including opposing source and drain terminals or regions flanking a centrally-located body node or well. Above the body node or well is formed the H-shaped gate terminal of the transistor. One or more shunt body contacts or ties bisect the source terminal and connect the source terminal of the transistor to the underlying body node. In this way, the body node or well is no longer electrically floating, but, instead, is connected to the fixed ground potential of the source terminal of the transistor.

U.S. Pat. No. 6,521,959B2 filed Feb. 13, 2001, by Kim et al., entitled “SOI semiconductor integrated circuit for eliminating floating body effects in SOI MOSFETs and method of fabricating the same”, assigned to Samsung Electronics Co., Ltd. (KR), which is incorporated herein by reference, describes an SOI integrated circuit and a method of fabricating the SOI integrated circuit. At least one isolated transistor active region and a body line are formed on an SOI substrate. The transistor active region and the body line are surrounded by an isolation layer which is in contact with a buried insulating layer of the SOI substrate. A portion of the sidewall of the transistor active region is extended to the body line. Thus, the transistor active region is electrically connected to the body line through a body extension. The body extension is covered with a body insulating layer. An insulated gate pattern is formed over the transistor active region, and one end of the gate pattern is overlapped with the body insulating layer.

One drawback of the above-mentioned prior art disclosures is that the manufacturing process for making an SOI MOSFET device having H-gate or T-gate body tie configurations is complicated. Further, prior art body tied SOI device has poor device performance due to eliminated floating body effect. In addition, such body-tied SOI devices according to the prior art usually need an additional body contact that consumes a lot of chip surface area. Accordingly, there is a strong need to provide a high performance PD SOI MOSFET device and method for fabricating the same.

### SUMMARY OF INVENTION

The primary object of the present invention is to provide a high performance partially depleted (PD) SOI MOSFET device, which consumes relatively small chip surface area.

Another object of the present invention is to provide a high performance partially depleted (PD) SOI MOSFET device with high current-driving capability and raised kink triggering voltage.

Still another object of at least one preferred embodiment of the present invention is to provide a process for fabricating the high performance PD SOI MOSFET device, which consumes relatively small chip surface area.

According to the claimed invention, a partially depleted SOI MOS device is disclosed. The partially depleted SOI MOS device comprises a silicon wafer having a thin film body, a supporting substrate, and a buried oxide layer isolating the thin film body from the supporting substrate. The thin film body has a main surface. Oxide filled trenches, which extend downwards from the main surface as far as the buried layer, are provided. The trenches are disposed so as to fully enclose a volume of the thin film body, thereby forming a well on the main surface. A dielectric layer is disposed on the main surface. A polysilicon gate of first conductivity type is patterned on the dielectric layer. The polysilicon gate having two opposing long sides that extend from a first end over a first oxide filled trench across the well to a second end, wherein a portion of one of the ends of the polysilicon gate is implanted with ions of second conductivity type opposite to the first conductivity type, whereby a tunneling connection is formed between the well and the implanted portion of the polysilicon gate. Source and drain regions of first conductivity type is formed on opposite sides of the polysilicon gate.

According to another aspect of the present invention, a partially depleted SOI MOS device comprises a well of first conductivity type isolated in a thin film body of an SOI substrate. The SOI substrate comprises the thin film body, a support substrate, and a buried oxide layer interposed between the thin film body and the support substrate. A dielectric layer is disposed on a surface of the well. A polysilicon gate is patterned on the dielectric layer. The polysilicon gate consists of a first gate section of first conductivity type overlapping with an extended well region of the well and a second gate section of second conductivity type lying across the well, whereby a tunneling connection is formed between the first gate section and the extended well region of said well. Source and drain regions of second conductivity type are formed on opposite sides of the second gate section.

It is to be understood that both the foregoing general description and the following detailed description are exemplary, but are not restrictive, of the invention. Other objects, advantages, and novel features of the claimed invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a top view layout of one preferred embodiment of a PD SOI MOSFET device in accordance with the present invention;

FIG. 2 is a cross-sectional view taken from line A-A of FIG. 1, illustrating the cross-section along the length of the polysilicon gate and where the direct tunneling between the polysilicon gate and the floating body occurs;

FIG. 3 is a cross-sectional view taken from line B-B of FIG. 1;

FIG. 4 is a cross-sectional view taken from line C-C of FIG. 1;

FIG. 5 is a top view layout of another preferred embodiment of a PD SOI MOSFET device in accordance with the present invention; and

FIG. 6 plots drain current (I_{D}) vs. drain-to-source biases (V_{DS}) at different gate-to-source biases (V_{GS}) for a PD SOI PMOSFET device having a gate length of 0.12 microns.

### DETAILED DESCRIPTION

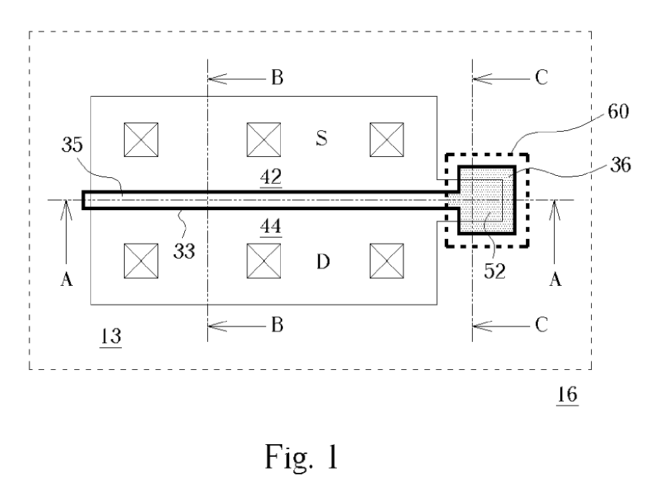

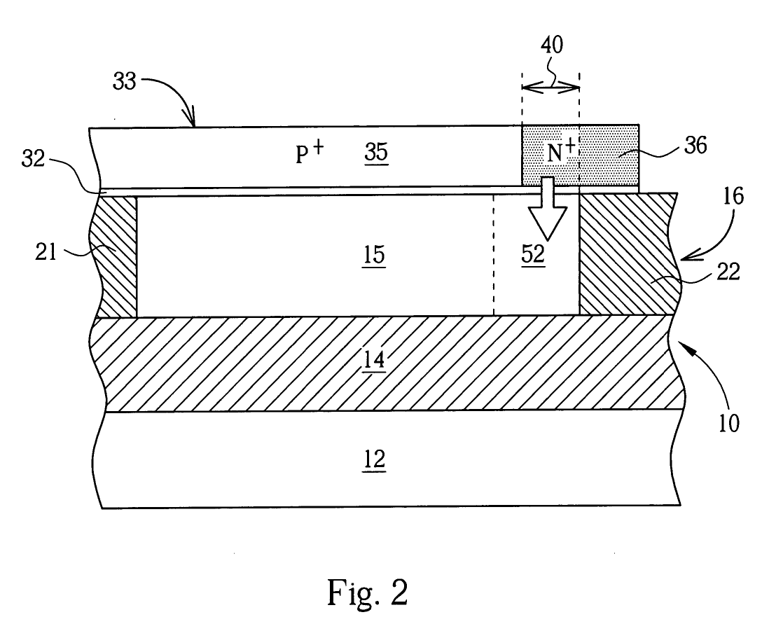

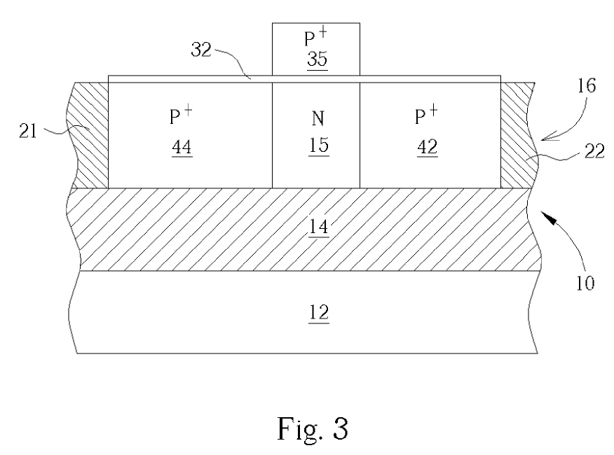

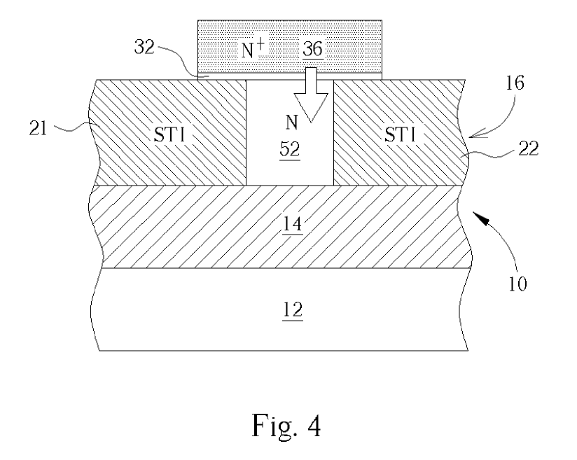

Please refer to FIG. 1 to FIG. 4, wherein FIG. 1 is a top view layout of one preferred embodiment of a PD SOI MOSFET in accordance with the present invention, FIG. 2, FIG. 3, and FIG. 4 are cross-sectional views taken from lines A-A, B-B, and C-C of FIG. 1, respectively. The first preferred embodiment of the present invention through FIGS. 1 to 4 demonstrates a PMOS SOI device. However, it is understood by those skilled in the art that the SOI integrated circuit of the present invention could be implemented using N-MOSFETs and P-MOSFETs by applying appropriate reversal of conductivity types. As shown in FIG. 1 and FIG. 2, a commercially available SOI substrate 10 is provided. The SOI substrate may be formed by any suitable method, such as the separation by implanted oxygen (SIMOX) method or the bonded-and-etch back (BESOI) method. By way of example, the SOI substrate 10 is a SIMOX wafer with a buried oxide insulation layer 14 supported by a support substrate 12. The thickness of the buried oxide insulation layer 14 is, for example, 1300˜1800 angstroms. The PD SOI integrated circuit of the present invention is fabricated on a P-type silicon thin film 16 overlying the buried oxide insulation layer 14.

A conventional lithographic process and an ion implantation process are carried out to form an N-well 13 in the P-type silicon thin film 16. More specifically, the PD SOI PMOS device according to the first preferred embodiment of the present invention is fabricated within the N-well 13. After well implantation, active areas (AA) are defined. Shallow trench isolation (STI) regions 21 and 22 (best seen in FIG. 2) are fabricated into the silicon thin film 16, reaching downwardly as far as the buried oxide insulation layer 14, thereby defining an electrically isolated body 15 therein.

As seen in FIG. 1 and FIG. 4, the electrically isolated body 15 includes an extended N type body region 52. Subsequently, gate dielectric layer 32 is formed on the top surface of the isolated body 15 by thermal growth. The gate dielectric layer 32 may be made of any material that is suitable for use as a gate dielectric, for example, silicon nitride, nitrogen contained silicon dioxide, oxynitride, or high K dielectric layer containing at least one of the metals selected from the group consisting of Al, Zr, La, Ta, Hf. The gate dielectric layer 32 has a thickness that is thin enough to implement electron/hole direct tunneling operations. Preferably, for example, the thickness of the gate dielectric layer 32 that is made of silicon dioxide is about 5˜120 angstroms. A conventional chemical vapor deposition (CVD) such as a low pressure CVD (LPCVD) is performed to deposit a polysilicon layer (not shown) on the gate dielectric layer 32. The polysilicon layer is then patterned and properly doped to form a polysilicon gate structure 33 having a P⁺ gate section 35 connected with extended N⁺ gate section 36 that overlaps with the extended N type body region 52. The extended N⁺ gate section 36 may be doped by using a photo mask having a window 60 exposing the portion of the polysilicon gate structure 33 directly overlying the extended N type body region 52. As best seen in FIG. 2, the overlapping area 40 between the N⁺ extended gate section 36 and the extended N type body region 52 is referred to as a direct tunneling area. In this embodiment, the N⁺ extended gate section 36 at one end of the polysilicon gate structure 33 provides a direct tunneling connection for electrons.

As shown in FIG. 1 and FIG. 3, using a suitable mask, high-dosage P type dopants such as boron are implanted into the isolated body 15 on opposite sides of the P⁺ gate section to a concentration between about 10¹⁹ and 10²⁰ ions/cm³, thereby forming P⁺ source/drain regions 42 and 44. The P⁺ source/drain regions 42 and 44 define a P channel underneath the P⁺ gate section 35.

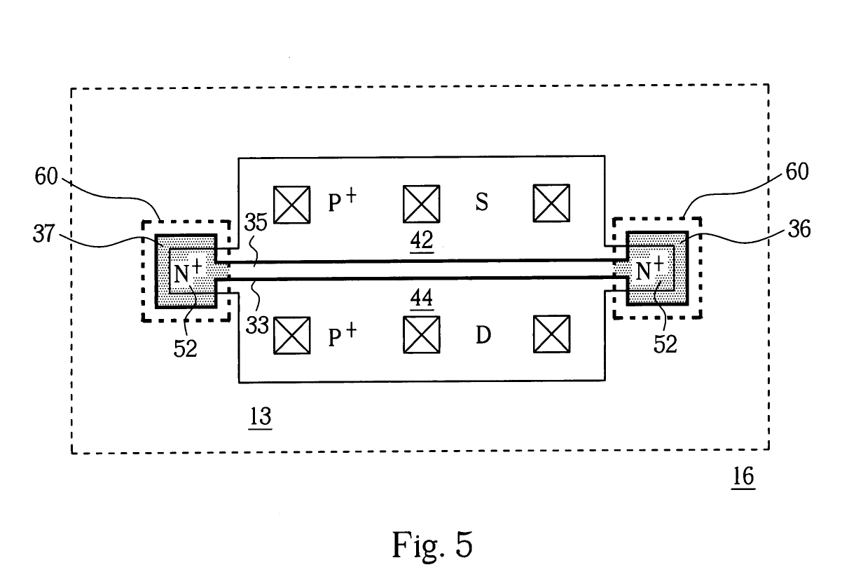

Please refer to FIG. 5. FIG. 5 demonstrates a top view layout of the second preferred embodiment of a PD SOI MOSFET device in accordance with the present invention. The PD SOI MOSFET device in accordance with the second preferred embodiment of the present invention is fabricated within an N-well 13 formed in a silicon thin film 16 of an SOI substrate (not explicitly shown). The SOI substrate is a commercially available SOI substrate, and may be formed by any suitable method, such as the separation by implanted oxygen (SIMOX) method or the bonded-and-etch back (BESOI) method. The second preferred embodiment of the present invention as set forth in FIG. 5 demonstrates a PMOS SOI device. However, it is understood by those skilled in the art that the SOI integrated circuit of the present invention could be implemented using N-MOSFETs and P-MOSFETs by applying appropriate reversal of conductivity types.

A conventional lithographic process and an ion implantation process are carried out to form an N-well 13 in the P-type silicon thin film 16. More specifically, the PD SOI PMOS device according to the second preferred embodiment of the present invention is fabricated within the N-well 13. After well implantation, active areas (AA) are defined. The PD SOI MOS device according to the second preferred embodiment of the present invention comprises oxide filled STI trenches that extend downwards from the main surface of the silicon thin film 16 as far as the buried oxide layer (not shown) in the SOI substrate. The STI trenches are disposed so as to fully enclose a volume of the thin film body 16, thereby forming a well on the main surface of the thin film body 16. Agate dielectric layer is disposed on the well. A polysilicon gate 33 is disposed on the dielectric layer. The polysilicon gate 33 having two opposing long sides that extend from a first end 36 over a first oxide filled trench across the well to a second end 37 over a first second oxide filled trench. A portion of each of the ends 36 and 37 of the polysilicon gate 33 is implanted with N type ions. The implantation may be carried out using a photo mask having a window 60 exposing the portions of the polysilicon gate 33 that directly overlie the extended N type body region 52. The rest portion of the polysilicon gate 33 is implanted with P type ions using a suitable mask. A tunneling connection is formed between the well and the implanted portion of the polysilicon gate 33. P⁺ source and drain regions are formed on opposite sides of the polysilicon gate 33.

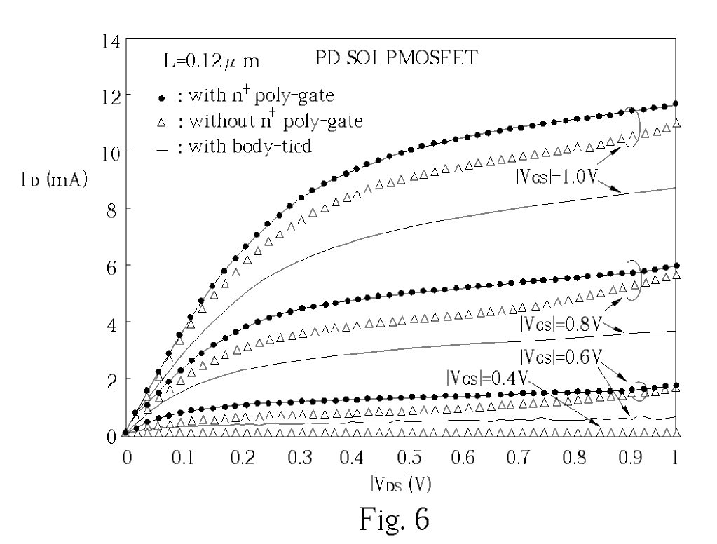

In comparison with the prior art, the present invention PD SOI MOS device has superior performance in terms of current-driving capability and kink-triggering voltage. Advantageously, referring to FIG. 6, the present invention PD SOI MOS device (configured with N⁺ poly direct tunneling gate) exhibits enhanced current-driving capability and raised kink-triggering voltage when comparing to the prior art structures (without N⁺ poly direct tunneling gate). According to the first preferred embodiment of this invention, it is believed that the electron direct tunneling is implemented via ECB (Electron-Conduction Band) mechanism, but not through EVB (Electron-Valence Band) mechanism. This is because EVB mechanism does not exist when the oxide voltage drop is less than 1V. During operation, the channel electrical field near the drain is reduced, thereby suppressing the kink effect.

Those skilled in the art will readily observe that numerous modifications and alterations of the present invention may be made while retaining the teachings of the invention. Accordingly, the above disclosure should be construed as limited only by the metes and bounds of the appended claims.

1. A partially depleted SOI MOS device comprising:
a well of first conductivity type isolated in a thin film body of an SOI substrate, said SOI substrate comprising said thin film body, a support substrate and a buried oxide layer interposed between said thin film body and said support substrate;
a gate dielectric layer on a surface of said well;
a polysilicon gate on said gate dielectric layer, said polysilicon gate consisting of a first gate section of first conductivity type overlapping and capacitively coupling with an extended well region of said well and a second gate section of second conductivity type lying across said well, whereby a tunneling connection is formed between said first gate section and said extended well region of said well, wherein said polysilicon gate is not electrically connected to said well or said extended well region; and
source and drain regions of second conductivity type on opposite sides of said second gate section.

2. The partially depleted SOI MOS device according to claim 1 wherein said gate dielectric layer is selected from the group consisting of silicon dioxide, nitrogen contained silicon dioxide, oxynitride, and Al, Zr, La, Ta, or Hf contained high K dielectric layer.

3. The partially depleted SOI MOS device according to claim 1 wherein said dielectric layer has a thickness of between about 5˜120 angstroms.

4. The partially depleted SOI MOS device according to claim 1 wherein said thin film body is a silicon layer.

5. The partially depleted SOI MOS device according to claim 1 wherein said first conductivity type is N type, and said second conductivity type is P type.

6. The partially depleted SOI MOS device according to claim 1 wherein said first conductivity type is P type, and said second conductivity type is N type.

7. A partially depleted SOI MOS device comprising:
a silicon wafer having a thin film body, a supporting substrate, and a buried oxide layer isolating said thin film body from said supporting substrate, said thin film body having a main surface;
oxide filled trenches that extend downwards from said main surface as far as said buried layer, said trenches being disposed so as to fully enclose a volume of said thin film body, thereby forming a well on said main surface;
a gate dielectric layer on said main surface;
a polysilicon gate of first conductivity type on said gate dielectric layer, said polysilicon gate having two opposing long sides that extend from a first end of said polysilicon gate over a first oxide filled trench across said well to a second end of said polysilicon gate over a second oxide filled trench, wherein a portion of one of said ends of said polysilicon gate is implanted with ions of second conductivity type opposite to said first conductivity type, whereby a tunneling connection is formed between said well and said implanted portion of said polysilicon gate, and wherein said polysilicon gate is not electrically connected to said well; and
source and drain regions of first conductivity type on opposite sides of said polysilicon gate, whereby during operation, a channel electrical field near said drain region is reduced.

8. The partially depleted SOI MOS device according to claim 7 wherein said dielectric layer is selected from the group consisting of silicon dioxide, nitrogen contained silicon dioxide, oxynitride, and Al, Zr, La, Ta, or Hf contained high K dielectric layer.

9. The partially depleted SOI MOS device according to claim 7 wherein said dielectric layer has a thickness of between about 5˜120 angstroms.

10. The partially depleted SOI MOS device according to claim 7 wherein said thin film body is a silicon layer.

11. The partially depleted SOI MOS device according to claim 7 wherein said first conductivity type is P type, and said second conductivity type is N type.

12. The partially depleted SOI MOS device according to claim 7 wherein said first conductivity type is N type, and said second conductivity type is P type.
